(19) United States
(12) Patent Application Publication
(10) Pub. No.: US 2006/0148195 A1
(43) Pub. Date: Jul. 6, 2006

(54) Manufacturing isolation layer in CMOS image sensor

(76) Inventor: Joon Hwang, Cheongju city (KR)

Correspondence Address: Song K. Jung;MCKENNA LONG & ALDRIDGE LLP, 1900 K. Street, N.W., Washington, DC, 20006, US

(21) Appl. No.: 11/319,483

(22) Filed: Dec. 29, 2005

(30) Foreign Application Priority Data
Dec. 30, 2004 (KR) 2004-0117225

(51) Int. Cl. H01L 21/76

(52) U.S. Cl. 438/423

(57) ABSTRACT

A method of manufacturing an isolation layer in a CMOS image sensor injects oxygen and P-type ions into a device isolation region without etching damage and performs a heating process to form a device isolation layer in a semiconductor substrate. An ion injection mask layer is formed that exposes a device isolation region on a low concentration first conductive type semiconductor substrate. Oxygen ions are injected into the semiconductor substrate using the mask layer. A heating process is performed to form an oxide layer in the device isolation region. A gate insulating layer is formed on the semiconductor substrate and a gate electrode is formed on the gate insulating layer. A low concentration second conductive type diffusion region is formed in a photodiode region. A high concentration second conductive type diffusion region is formed at both sides of the gate electrode in the semiconductor substrate. A first conductive type diffusion region haying a concentration higher than that of the semiconductor substrate is formed on the low concentration second conductive type diffusion region in the semiconductor substrate.

### CROSS-REFERENCE TO RELATED APPLICATION

This application claims the benefit of Korean Patent Application No. 10-2004-0117225, filed on Dec. 30, 2004, which is hereby incorporated by reference as if fully set forth herein.

### BACKGROUND OF THE INVENTION

1. Field of the Invention

The present invention relates to a CMOS image sensor and more particularly, to a method of manufacturing an isolation layer in a CMOS image sensor. The method can inject oxygen and P-type ions into a device isolation region without sustaining etching damage and performs a heating process to form an device isolation layer in a semiconductor substrate.

2. Discussion of the Related Art

An image sensor is a semiconductor device for converting an optical image into an electrical signal. A typical complementary metal-oxide-silicon (CMOS) image sensor includes a charge-coupled device, in which charge carriers are stored in metal-oxide-silicon capacitors that are very close to each other, and MOS transistors to correspond to the number of pixels, which are manufactured using a CMOS technology. Using the MOS transistors, the output signals are detected by a control circuit and a signal processing circuit located in a peripheral circuit area.

The CMOS image sensor for converting an optical image into an electrical signal can include signal processing chips having a photodiode. An amplifier, an analog/digital converter, an internal voltage generator, a timing generator, and digital logic may be connected on one chip, thereby reducing space, power, and cost. A charge coupled device is manufactured through a specialized method, while the CMOS image sensor is manufactured using a method of etching a silicon wafer, which is cheaper than the method of manufacturing the charge coupled device. Thus, the CMOS image sensor can be advantageously mass produced and have a high degree of integration.

Referring to FIG. 1, illustrating a CMOS image sensor according to the related art, a low concentration P-type epitaxial layer 111 is grown on a high concentration P-type substrate 110, and a shallow-trench isolation region 118 for isolating elements is formed by providing a trench in the epitaxial layer 111 and filling the trench with an insulating layer. A gate insulating layer 116 is formed on the epitaxial layer 111, including on the shallow-trench isolation region 118, and a gate electrode 119 composed of polysilicon is formed on the gate insulating layer 116. A photoresist pattern (not shown) is formed on the epitaxial layer 111, including on the gate electrode 119, and a low concentration N-type diffusion region 121 having high energy is formed in a photodiode region by ion injection using the photoresist pattern as a mask (not shown). The photoresist pattern is removed; spacers 122 are formed on both sides of the gate electrode 119; and a high concentration N-type diffusion region 123 is formed.

P-type impurities are injected into the epitaxial layer 111 at a concentration lower than that of the substrate 110 and higher than that of the epitaxial layer 111 to form a P-type diffusion region 124 on the low concentration N-type diffusion region 121 in the photodiode region.

In the CMOS image sensor manufactured by the aforementioned method, the device isolation layer is formed by the shallow-trench isolation and a photodiode having a P-N-P structure is formed in the photodiode region. The shallow-trench isolation region is formed by etching the semiconductor substrate to form the trench and filling the trench with the insulating layer. When the semiconductor substrate is etched, a silicon lattice can suffer from etching damage. Furthermore, since the trench is included in the photodiode region, an unnecessary interface trap is made at the interface of the shallow-trench isolation region. Accordingly, junction leakage current increases, and noise characteristics of the image sensor deteriorates.

### SUMMARY OF THE INVENTION

Accordingly, the present invention is directed to a method of manufacturing an isolation layer of a CMOS image sensor that can substantially obviate one or more disclosed or undisclosed problems or issues that may be due to limitations and disadvantages of the related art.

The present invention includes a method of manufacturing an isolation layer of a CMOS image sensor that can form a device isolation layer without etching a semiconductor substrate to reduce leakage current generated by a trap as a result of etching damage and to generally improve the characteristics of the image sensor.

Additional advantages, objects, and features of the invention will be set forth in part in the description which follows and will become apparent to those having ordinary skill in the art upon examination of the following. The objectives and other advantages of the invention may be realized and attained by the structure particularly pointed out in the written description.

To achieve these and other advantages in accordance with the purpose of the invention, as embodied and broadly described herein, an exemplary method of manufacturing an isolation layer of a CMOS image sensor comprises forming an ion injection mask layer which exposes a device isolation region on a semiconductor substrate; injecting oxygen ions into the semiconductor substrate using the mask layer; and performing a heating process to form an oxide layer in the device isolation region.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the invention. In the drawings:

FIG. 1 is a cross-sectional view of a CMOS image sensor according to the prior art; and

FIGS. 2A-2C are cross-sectional views illustrating a method of manufacturing an isolation layer in a CMOS image sensor according to the present invention.

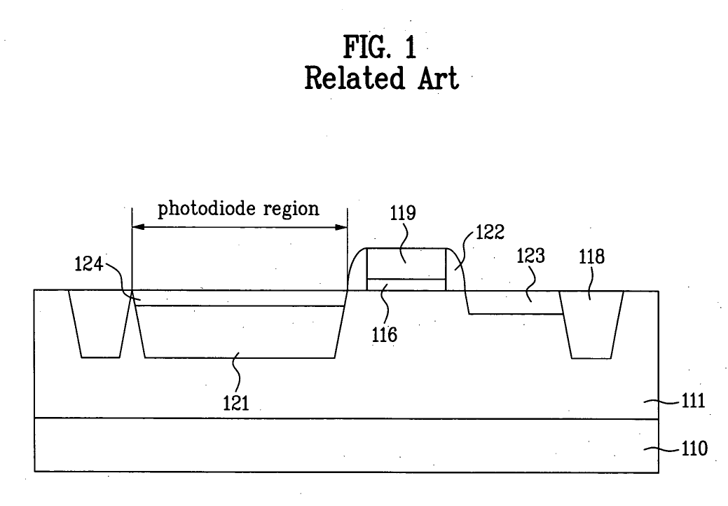

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

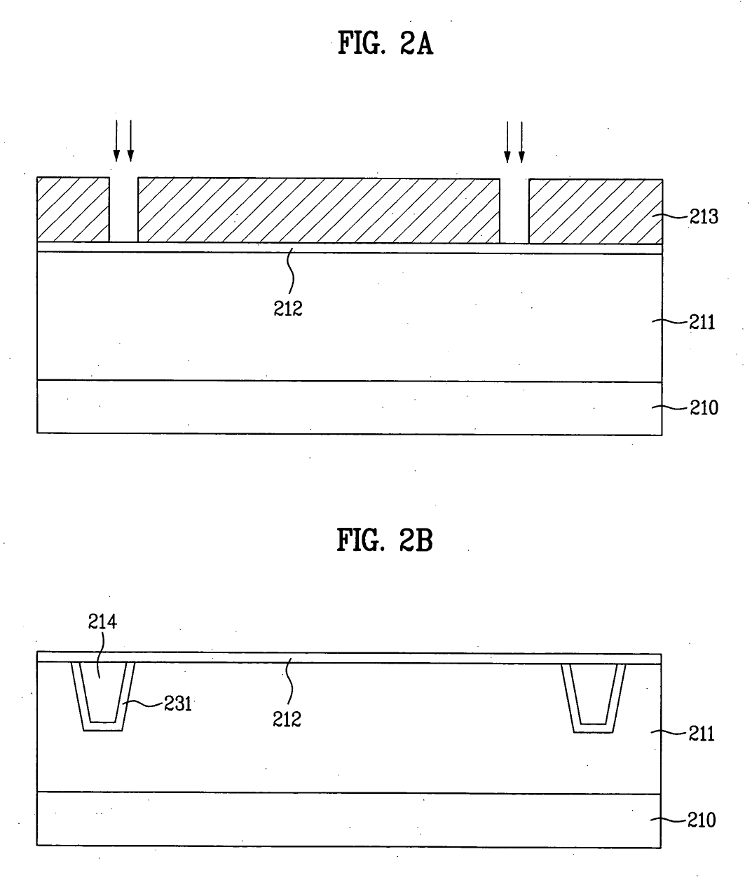

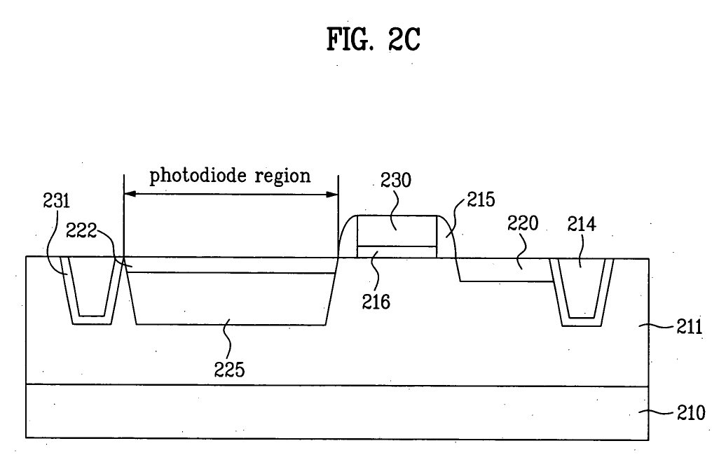

FIGS. 2A-2C illustrate an exemplary method of manufacturing an isolation layer in a CMOS image sensor according to the present invention.

As illustrated in FIG. 2A, a low concentration P-type epitaxial layer 211 is grown on a high concentration P-type substrate 210, and a pad oxide layer 212 is grown on the epitaxial layer 211. A photoresist (not shown) is coated on the pad oxide layer 212 and is exposed and developed to form a photoresist pattern 213 that exposes a device isolation region. Oxygen ions and high concentration P-type impurities are sequentially injected into the epitaxial layer 211 using the photoresist pattern 213 as a mask. The semiconductor substrate and the injected impurities can have different conductivity. The oxygen ion injection can be performed using a conventional ion injector.

As illustrated in FIG. 2B, the photoresist pattern 213 is removed and a heating process is performed to form an oxide layer 214, which functions as a device isolation layer by the reaction between the oxygen and the silicon in the epitaxial layer 213 in the device isolation region. The high concentration P-type impurities are diffused to form an isolation layer diffusion region 231 surrounding the oxide layer 214.

As illustrated in FIG. 2C, a gate insulating layer 216 is grown on the epitaxial layer 211 and a gate electrode 230 composed of polysilicon is formed on the gate insulating layer 216. Spacers 215 are formed on both sides of the gate electrode 230. Ions are injected into a photodiode region at a high energy of about 150-250 KeV to form a low concentration N-type diffusion region 225. High concentration N-type diffusion regions 220, which are source and drain regions, are formed, for example, at both sides of the gate electrode 214 in the epitaxial layer 211. P-type impurities are injected into the epitaxial layer 211 at a concentration lower than that of the substrate 210 and higher than that of the epitaxial layer 211 to form a P-type diffusion region 222 on the low concentration N-type diffusion region 221 in the photodiode region.

According to the present invention, since a device isolation layer is formed without etching a semiconductor substrate, it is possible to reduce leakage current generated by a trap as a result of etching damage, and as such, improve characteristics of the image sensor.

It will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. A method of manufacturing an isolation layer in a CMOS image sensor, comprising:
forming an ion injection mask layer that exposes a device isolation region on a semiconductor substrate;
injecting oxygen ions into the semiconductor substrate using the mask layer; and
performing a heating process to form an oxide layer in the device isolation region.

2. The method according to claim 1, further comprising injecting P-type impurities into the semiconductor substrate using the mask layer.

3. The method according to claim 2, wherein the P-type impurities are injected at a concentration higher than that of the semiconductor substrate.

4. The method according to claim 1, further comprising injecting impurities into the semiconductor substrate using the mask layer.

5. The method according to claim 4, wherein the semiconductor substrate is of a first conductivity and wherein the injected impurities are of a second conductivity.

6. The method according to claim 1, further comprising.
forming a gate insulating layer on the semiconductor substrate;
forming a gate electrode on the gate insulating layer;
forming a low concentration second conductive type diffusion region in a photodiode region;
forming a high concentration second conductive type diffusion region at both sides of the gate electrode in the semiconductor substrate; and
forming a first conductive type diffusion region having a concentration higher than that of the semiconductor substrate on the low concentration second conductive type diffusion region in the semiconductor substrate

7. A method of manufacturing an isolation layer in a CMOS image sensor, comprising:
forming an ion injection mask layer that exposes a device isolation region on a low concentration first conductive type semiconductor substrate;
injecting oxygen ions into the semiconductor substrate using the mask layer;
performing a heating process to form an oxide layer in the device isolation region;
forming a gate insulating layer on the semiconductor substrate and forming a gate electrode on the gate insulating layer;
forming a low concentration second conductive type diffusion region in a photodiode region;
forming a high concentration second conductive type diffusion region at both sides of the gate electrode in the semiconductor substrate; and
forming a first conductive type diffusion region having a concentration higher than that of the semiconductor substrate on the low concentration second conductive type diffusion region in the semiconductor substrate.

8. The method according to claim 7, wherein the low concentration N-type diffusion region is formed in the photodiode region by an ion implantation process using an energy of about 150-250 KeV.

9. The CMOS image sensor manufactured according to the method at claim 1.

10. The CMOS image sensor manufactured according to the method of claim 7.
